(19) United States
(12) Patent Application Publication
(10) Pub. No.: US 2025/0362600 A1
(43) Pub. Date: Nov. 27, 2025

(54) PHOTOSENSITIVE RESIN COMPOSITION, PHOTOSENSITIVE ELEMENT, PRINTED WIRING BOARD, AND METHOD FOR MANUFACTURING PRINTED WIRING BOARD

(71) Applicant: Resonac Corporation, Tokyo (JP)

(72) Inventors: Naoki YAMASHITA, Tokyo (JP); Hayato SAWAMOTO, Tokyo (JP); Kaho YAMAGUCHI, Tokyo (JP); Arisa YAMAKAWA, Tokyo (JP)

(21) Appl. No.: 18/859,085

(22) PCT Filed: Jan. 31, 2024
(86) PCT No.: PCT/JP2024/003089

§ 371 Date: Oct. 22, 2024

(30) Foreign Application Priority Data
Feb. 6, 2023 (JP) 2023-016093

(51) Int. Cl. G03F 7/031; G03F 7/029; G03F 7/033; G03F 7/105; H05K 3/06

(52) U.S. Cl. CPC G03F 7/031; G03F 7/029; G03F 7/033; G03F 7/105; H05K 3/064

(57) ABSTRACT

A photosensitive resin composition, containing: an acid-modified vinyl group-containing resin (A); a photopolymerization initiator (B); a photopolymerizable compound (C); and a thermosetting resin (D), in which the acid-modified vinyl group-containing resin (A) contains a first resin with a weight average molecular weight of less than 4000, and a second resin with a weight average molecular weight of 4000 or more, a content of the first resin is greater than 60% by mass, on the basis of a total amount of the acid-modified vinyl group-containing resin (A), and a content of the acid-modified vinyl group-containing resin (A) is 33% by mass or less, on the basis of a total solid content of the photosensitive resin composition.

### TECHNICAL FIELD

The present disclosure relates to a photosensitive resin composition, a photosensitive element, a printed circuit board, and a method for producing a printed circuit board.

### BACKGROUND ART

Recently, a printed circuit board has been densified in accordance with an increase in the number of circuit layers and the miniaturization of wiring. In particular, a semiconductor package substrate such as a ball grid array (BGA) and a chip size package (CSP), on which a semiconductor chip is mounted, has been significantly densified, and in addition to the miniaturization of the wiring, there has been a demand for a further reduction in the diameter of a via (also referred to as a “via hole”) for interlayer connection.

As a photosensitive resin composition for forming an interlayer dielectric layer, for example, a photosensitive resin composition containing an alkali-soluble resin having a carboxyl group and an ethylenically unsaturated group in the molecules, a photopolymerization initiator, and a cyanate ester compound (refer to Patent Literature 1), a photosensitive resin composition containing an acid-modified vinyl group-containing epoxy resin, a photopolymerizable compound, a photopolymerization initiator, an inorganic filler, and a silane compound, in which the content of the inorganic filler is 20 to 60% by mass, on the basis of the total solid content in the photosensitive resin composition (refer to Patent Literature 2), and the like are known.

### CITATION LIST

### Patent Literature

Patent Literature 1: Japanese Unexamined Patent Publication No. 2019-66793
Patent Literature 2: Japanese Unexamined Patent Publication No. 2017-116652

### SUMMARY OF INVENTION

### Technical Problem

In accordance with a further reduction in the diameter of the via for interlayer connection, the photosensitive resin composition for forming an interlayer dielectric layer is required to be capable of reducing a residue in the bottom portion of the via when formed.

Therefore, an object of the present disclosure is to provide a photosensitive resin composition capable of reducing a residue in the bottom portion of a via when formed, and a photosensitive element, a printed circuit board, and a method for producing a printed circuit board, using the photosensitive resin composition.

### Solution to Problem

In order to attain the object described above, the present disclosure provides a photosensitive resin composition, a photosensitive element, a printed circuit board, and a method for producing a printed circuit board described below.
[1] A photosensitive resin composition, containing: an acid-modified vinyl group-containing resin (A); a photopolymerization initiator (B); a photopolymerizable compound (C); and a thermosetting resin (D), in which the acid-modified vinyl group-containing resin (A) contains a first resin with a weight average molecular weight of less than 4000, and a second resin with a weight average molecular weight of 4000 or more, a content of the first resin is greater than 60% by mass, on the basis of a total amount of the acid-modified vinyl group-containing resin (A), and a content of the acid-modified vinyl group-containing resin (A) is 33% by mass or less, on the basis of a total solid content of the photosensitive resin composition.
[2] The photosensitive resin composition according to [1] described above, in which the first resin includes acid-modified epoxy (meth)acrylate having an alicyclic skeleton.
[3] The photosensitive resin composition according to [1] or [2] described above, in which the second resin includes acid-modified epoxy (meth)acrylate not having an alicyclic skeleton.
[4] The photosensitive resin composition according to any of [1] to [3] described above, in which a content of the second resin is 5% by mass or more, on the basis of the total amount of the acid-modified vinyl group-containing resin (A).
[5] The photosensitive resin composition according to any of [1] to [4] described above, further containing an inorganic filler (E).
[6] The photosensitive resin composition according to any of [1] to [5] described above, further containing a pigment (F).
[7] A photosensitive element, including; a support film; and a photosensitive layer formed on the support film, in which the photosensitive layer contains the photosensitive resin composition according to any of [1] to [6] described above.
[8] A printed circuit board, including an interlayer dielectric layer including a cured product of the photosensitive resin composition according to any of [1] to [6] described above.
[9] A method for producing a printed circuit board, including: a step of forming a photosensitive layer on a substrate by using the photosensitive resin composition according to any of [1] to [6] described above; a step of exposing and developing the photosensitive layer to form a resist pattern; and a step of curing the resist pattern to form an interlayer dielectric layer.
[10] A method for producing a printed circuit board, including: a step of forming a photosensitive layer on a substrate by using the photosensitive element according to [7] described above; a step of exposing and developing the photosensitive layer to form a resist pattern; and a step of curing the resist pattern to form an interlayer dielectric layer.

### Advantageous Effects of Invention

According to the present disclosure, it is possible to provide the photosensitive resin composition capable of reducing the residue in the bottom portion of the via when formed, and the photosensitive element, the printed circuit board, and the method for producing a printed circuit board, using the photosensitive resin composition.

### BRIEF DESCRIPTION OF DRAWINGS

FIG. 1 is a cross-sectional view schematically illustrating a photosensitive element according to this embodiment.

FIG. 2 is a schematic view illustrating one aspect of a method for producing a printed circuit board of this embodiment.

### DESCRIPTION OF EMBODIMENTS

Hereinafter, the present disclosure will be described in detail. In this specification, the term “step” includes not only an independent step but also a step that is not explicitly distinguishable from other steps insofar as a desired function of the step is attained. The term “layer” includes not only a structure in which a layer is formed on the entire surface but also a structure in which a layer is formed on a part of the surface when observed as a plan view.

In this specification, a numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage, or may be replaced with values described in Examples. In this specification, for example, the expression “10 or more” indicates 10 and a numerical value greater than 10, which also applies to other numerical values. In addition, for example, the expression “10 or less” indicates 10 and a numerical value less than 10, which also applies to other numerical values.

In this specification, in a case where there are a plurality of substances corresponding to each component in a composition, the content of each component in the composition indicates the total amount of the plurality of substances in the composition, unless otherwise specified. In this specification, the “number of ring members” is the number of carbon atoms required to form a ring, and does not include the number of carbon atoms of a substituent in the ring. In this specification, “(meth)acrylate” indicates at least one of “acrylate” and “methacrylate” corresponding thereto, and the same also applies to other similar expressions such as a (meth)acrylic acid. In this specification, a “solid content” indicates a non-volatile content excluding a volatile substance (water, a solvent, or the like) in a photosensitive resin composition, and also includes a component in the form of a liquid, syrup, or a wax at a room temperature (approximately 25° C.).

### [Photosensitive Resin Composition]

A photosensitive resin composition according to this embodiment contains an acid-modified vinyl group-containing resin (A), a photopolymerization initiator (B), a photopolymerizable compound (C), and a thermosetting resin (D). The acid-modified vinyl group-containing resin (A) contains a first resin with a weight average molecular weight of less than 4000, and a second resin with a weight average molecular weight of 4000 or more. The content of the first resin is greater than 60% by mass, on the basis of the total amount of the acid-modified vinyl group-containing resin (A). The content of the acid-modified vinyl group-containing resin (A) is 33% by mass or less, on the basis of the total amount of the photosensitive resin composition. The photosensitive resin composition having the configuration described above is capable of reducing a residue in the bottom portion of a via when formed. The photosensitive resin composition according to this embodiment is a negative photosensitive resin composition, and a cured product of the photosensitive resin composition can be preferably used as a permanent resist such as an interlayer dielectric layer. Hereinafter, each component used for the photosensitive resin composition of this embodiment will be described in detail.

### (Component (A): Acid-Modified Vinyl Group-Containing Resin)

The photosensitive resin composition according to this embodiment contains the acid-modified vinyl group-containing resin as a component (A). The acid-modified vinyl group-containing resin is not particularly limited insofar as the acid-modified vinyl group-containing resin has a vinyl group that is a photopolymerizable ethylenically unsaturated bond and an alkali-soluble acid group. Examples of the acid group in the component (A) include a carboxy group, a sulfo group, and a phenolic hydroxyl group. Among them, from the viewpoint of a resolution, the carboxy group is preferable.

Examples of the acid-modified vinyl group-containing resin include acid-modified epoxy (meth)acrylate. The acid-modified epoxy (meth)acrylate is a resin in which epoxy (meth)acrylate that is a reactant between an epoxy resin and an organic acid having a vinyl group is subjected to acid modification. As the acid-modified epoxy (meth)acrylate, for example, an addition reactant in which a saturated or unsaturated polybasic anhydride (c) is added to an esterified product obtained by a reaction between an epoxy resin (a) and a vinyl group-containing monocarboxylic acid (b) can be used.

Examples of the epoxy resin (a) include a bisphenol novolac-type epoxy resin, a novolac-type epoxy resin, a bisphenol A-type epoxy resin, a bisphenol F-type epoxy resin, a triphenol methane-type epoxy resin, a biphenyl-type epoxy resin, a naphthalene-type epoxy resin, and a dicyclopentadiene-type epoxy resin.

Examples of the vinyl group-containing monocarboxylic acid (b) include a (meth)acrylic acid or a derivative thereof, such as an acrylic acid, a dimer of an acrylic acid, a methacrylic acid, β-furfuryl acrylate, β-styryl acrylate, a cinnamic acid, a crotonic acid, and an α-cyanocinnamic acid, a half ester compound that is a reaction product between hydroxyl group-containing (meth)acrylate and a dibasic acid anhydride, and a half ester compound that is a reaction product between vinyl group-containing monoglycidyl ether or vinyl group-containing monoglycidyl ester and a dibasic acid anhydride.

Examples of the hydroxyl group-containing (meth)acrylate, the vinyl group-containing monoglycidyl ether, and the vinyl group-containing monoglycidyl ester include hydroxyethyl acrylate, hydroxyethyl methacrylate, hydroxypropyl acrylate, hydroxypropyl methacrylate, hydroxybutyl acrylate, hydroxybutyl methacrylate, polyethylene glycol monoacrylate, polyethylene glycol monomethacrylate, trimethylol propane diacrylate, trimethylol propane dimethacrylate, pentaerythritol triacrylate, pentaerythritol trimethacrylate, dipentaerythritol pentaacrylate, pentaerythritol pentamethacrylate, glycidyl acrylate, and glycidyl methacrylate.

Examples of the dibasic acid anhydride include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride.

Examples of the saturated or unsaturated polybasic anhydride (c) include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride. Among them, from the viewpoint of being more excellent in the resolution, the tetrahydrophthalic anhydride may be used.

Examples of the acid-modified epoxy (meth)acrylate include acid-modified epoxy (meth)acrylate (A1) having an alicyclic skeleton, and acid-modified epoxy (meth)acrylate (A2) not having an alicyclic skeleton. From the viewpoint of being more excellent in the resolution, and the bonding adhesiveness and the electrical insulating reliability of the cured product, and being capable of further reducing the residue in the bottom portion of the via when formed, it is preferable that the component (A) includes the component (A1).

The number of ring members of the alicyclic skeleton in the component (A1), from the viewpoint of being more excellent in the resolution, and the bonding adhesiveness and the electrical insulating reliability of the cured product, and being capable of further reducing the residue in the bottom portion of the via when formed, is preferably 5 to 20, more preferably 5 to 18, even more preferably 6 to 18, particularly preferably 8 to 14, and extremely preferably 8 to 12. From the same viewpoint, the number of rings of the alicyclic skeleton in the component (A1) is preferably 2 or more, more preferably 2 to 4, and even more preferably 3. Examples of the alicyclic skeleton having one ring include a cyclohexane skeleton and a cyclohexene skeleton, and examples of the alicyclic skeleton having two or more rings include a norbornane skeleton, a decalin skeleton, a bicycloundecane skeleton, and a saturated dicyclopentadiene skeleton.

The component (A1), from the viewpoint of being more excellent in the resolution, and the bonding adhesiveness and the electrical insulating reliability of the cured product, and being capable of further reducing the residue in the bottom portion of the via when formed, has preferably a saturated dicyclopentadiene skeleton, and more preferably a saturated dicyclopentadiene skeleton represented by Formula (a) described below, as the alicyclic skeleton.

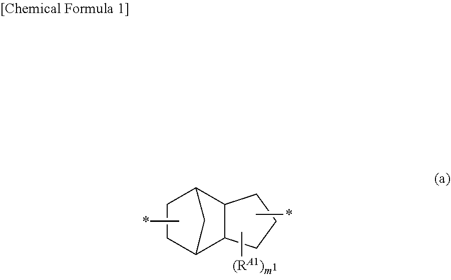

In Formula (a), R^{A1} represents an alkyl group having 1 to 12 carbon atoms, m¹ is an integer of 0 to 6, and * is a bonding site with respect to other structures.

Examples of the alkyl group having 1 to 12 carbon atoms, represented by R^{A1}, include a methyl group, an ethyl group, a n-propyl group, an isopropyl group, a n-butyl group, an isobutyl group, a t-butyl group, and a n-pentyl group. From the viewpoint of being more excellent in the resolution, and the bonding adhesiveness and the electrical insulating reliability of the cured product, and being capable of further reducing the residue in the bottom portion of the via when formed, the alkyl group is preferably an alkyl group having 1 to 6 carbon atoms, more preferably an alkyl group having 1 to 3 carbon atoms, and even more preferably a methyl group.

m¹ is preferably an integer of 0 to 2, and more preferably 0. In a case where m¹ is an integer of 2 to 6, a plurality of R^{A1} 's may be identical to each other, or may be different from each other. The plurality of R^{A1}'s to an available extent, may be substituted on the same carbon atom, or may be substituted on different carbon atoms.

As the component (A1), for example, an addition reactant in which the saturated or unsaturated polybasic anhydride (c) is added to an esterified product obtained by a reaction between an epoxy resin (a1) having an alicyclic skeleton and the vinyl group-containing monocarboxylic acid (b) can be used.

Examples of the epoxy resin (a1) include a glycidyl ether-type epoxy resin, a glycidyl amine-type epoxy resin, and a glycidyl ester-type epoxy resin. Among them, the glycidyl ether-type epoxy resin is preferable.

As the epoxy resin (a1), an epoxy resin represented by Formula (a1-1) described below, or an epoxy resin having a structural unit represented by Formula (a1-2) described below is preferable.

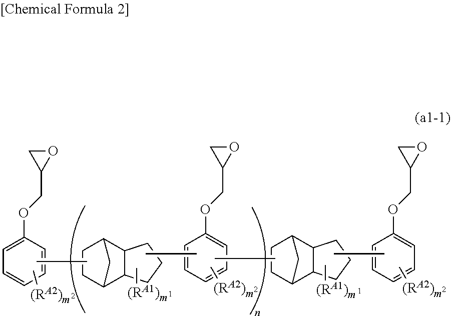

In Formula (a1-1), R^{A1} and m¹ are the same as R^{A1} and m¹ in Formula (a), R^{A2} represents an alkyl group having 1 to 12 carbon atoms, m² is an integer of 0 to 3, and n represents the number of structural units in parenthesis, which is 0 to 10.

The alkyl group having 1 to 12 carbon atoms, represented by R^{A2}, may be the alkyl groups exemplified as R^{A1}. m² is preferably 0 or 1, and more preferably 0. In a case where the epoxy resin is a mixture of epoxy resins having different numbers of structural units in parenthesis, n represents the average value of the mixture. It is preferable that n is 2 to 10.

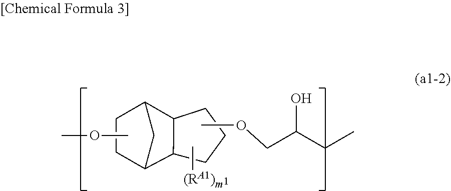

In Formula (a1-2), R^{A1} and m¹ are the same as R^{A1} and m¹ in Formula (a).

Examples of a commercially available product of the epoxy resin (a1) include a dicyclopentadiene-type epoxy resin such as XD-1000 (manufactured by Nippon Kayaku Co., Ltd., Product Name), and EPICLON HP-7200L, EPICLON HP-7200, EPICLON HP-7200HH, and EPICLON HP-7200HHH (manufactured by DIC Corporation, Product Name, “EPICLON” (Registered Trademark)).

As the component (A2), for example, an addition reactant in which the saturated or unsaturated polybasic anhydride (c) is added to an esterified product obtained by a reaction between an epoxy resin (a2) not having an alicyclic skeleton and the vinyl group-containing monocarboxylic acid (b) can be used.

Examples of the epoxy resin (a2) include a bisphenol-based epoxy resin such as a bisphenol A-type epoxy resin, a bisphenol F-type epoxy resin, and a bisphenol S-type epoxy resin; a bisphenol-based novolac-type epoxy resin such as a bisphenol A novolac-type epoxy resin and a bisphenol F novolac-type epoxy resin; a phenol aralkyl-type epoxy resin; a stilbene-type epoxy resin; a naphthalene skeleton-containing epoxy resin such as a naphthalene-type epoxy resin, a naphthol novolac-type epoxy resin, a naphthol-type epoxy resin, a naphthol aralkyl-type epoxy resin, and a naphthylene ether-type epoxy resin; a biphenyl-type epoxy resin; a biphenyl aralkyl-type epoxy resin; a xylene-type epoxy resin; a dihydroanthracene-type epoxy resin; and an aliphatic chain epoxy resin. Among them, the bisphenol-based novolac-type epoxy resin is preferable, and the bisphenol F novolac-type epoxy resin is more preferable.

The acid value of the component (A) is not particularly limited. The acid value of the component (A), from the viewpoint of improving the solubility of an unexposed portion with respect to an alkaline aqueous solution, may be 30 mgKOH/g or more, 40 mgKOH/g or more, or 50 mgKOH/g or more. The acid value of the component (A), from the viewpoint of improving the electrical property of the cured product, may be 150 mgKOH/g or less, 120 mgKOH/g or less, or 100 mgKOH/g or less.

The component (A) contains the first resin with a weight average molecular weight (Mw) of less than 4000, and the second resin with a weight average molecular weight (Mw) of 4000 or more. As the first resin and the second resin, a component of which Mw satisfies the condition described above is used by being selected from the components (A) described above. The first resin may be the component (A1). The second resin may be the component (A2).

Mw of the first resin, from the viewpoint of further reducing the residue in the bottom portion of the via when formed, may be 3500 or less, 3000 or less, 2500 or less, or 2000 or less, and from the viewpoint of ensuring the resolution during developing, may be 500 or more, or 1000 or more. Mw of the second resin, from the viewpoint of being more excellent in the bonding adhesiveness of the cured product, may be 4500 or more, 5000 or more, 5500 or more, or 6000 or more, and from the viewpoint of adjusting a varnish viscosity during coating, may be 100000 or less, 50000 or less, or 10000 or less.

A difference between Mw of the first resin and Mw of the second resin, from the viewpoint of further reducing the residue in the bottom portion of the via when formed and being more excellent in the bonding adhesiveness of the cured product, may be 1000 or more, 1500 or more, 2000 or more, 2500 or more, 3000 or more, 3500 or more, or 4000 or more, and from the viewpoint of compatibility, may be 10000 or less, 9000 or less, 8000 or less, 7000 or less, or 6000 or less.

Mw of component (A) can be measured by a gel permeation chromatography (GPC) method. A value obtained by measurement, for example, in the following GPC condition, and conversion using a calibration curve of standard polystyrene can be set as Mw. The calibration curve can be created by using a five-sample set (“PStQuick MP-H” and “PStQuickB”, manufactured by Tosoh Corporation) as standard polystyrene.

### (GPC Condition)

GPC Equipment: high-speed GPC equipment “HCL-8320GPC” (manufactured by Tosoh Corporation)
Detector: a differential refractometer or a UV detector (manufactured by Tosoh Corporation)
Column: a column TSKgel SuperMultipore HZH (Column Length: 15 cm, Column Inner Diameter: 4.6 mm) (manufactured by Tosoh Corporation)
Eluent: tetrahydrofuran (THF)
Measurement Temperature: 40° C.
Flow Rate: 0.35 mL/minute
Sample Concentration: 10 mg/THF 5 mL
Injection Amount: 20 μL

In the component (A), the content of the first resin is greater than 60% by mass, on the basis of the total amount of the component (A). The content of the first resin, from the viewpoint of further reducing the residue in the bottom portion of the via when formed, may be 65% by mass or more, 68% by mass or more, or 70% by mass or more, on the basis of the total amount of the component (A), and from the viewpoint of the viscosity in the entire constituent composition, may be 95% by mass or less, 90% by mass or less, 85% by mass or less, or 80% by mass or less, on the basis of the total amount of the component (A).

In the component (A), the content of the second resin is less than 40% by mass, on the basis of the total amount of the component (A). The content of the second resin, from the viewpoint of increasing the molecular weight during patterning, may be 5% by mass or more, 10% by mass or more, 15% by mass or more, or 20% by mass or more, on the basis of the total amount of the component (A), and from the viewpoint of further reducing the residue in the bottom portion of the via when formed, may be 35% by mass or less, 32% by mass or less, or 30% by mass or less, on the basis of the total amount of the component (A).

The content of the component (A) in the photosensitive resin composition is 33% by mass or less, on the basis of the total solid content of the photosensitive resin composition. The content of the component (A), from the viewpoint of further reducing the residue in the bottom portion of the via when formed, may be 32% by mass or less, 31% by mass or less, 30% by mass or less, or 29% by mass or less, on the basis of the total solid content of the photosensitive resin composition, and from the viewpoint of ensuring the resolution during developing, may be 20% by mass or more, 22% by mass or more, or 25% by mass or more, on the basis of the total solid content of the photosensitive resin composition.

### (Component (B): Photopolymerization Initiator)

The photosensitive resin composition according to this embodiment contains the photopolymerization initiator as a component (B). The component (B) is not particularly limited insofar as the component is capable of polymerizing the component (A) or the like.

Examples of the component (B) include a benzoin compound such as benzoin, benzoin methyl ether, and benzoin isopropyl ether; an acetophenone compound such as acetophenone, 2,2-dimethoxy-2-phenyl acetophenone, 2,2-diethoxy-2-phenyl acetophenone, 1,1-dichloroacetophenone, 1-hydroxycyclohexyl phenyl ketone, 2-benzyl-2-dimethyl amino-1-(4-morpholinophenyl)-1-butanone, 2-methyl-[4-(methyl thio)phenyl]-2-morpholino-1-propane, and N,N-dimethyl aminoacetophenone; an anthraquinone compound such as 2-methyl anthraquinone, 2-ethyl anthraquinone, 2-tert-butyl anthraquinone, 1-chloroanthraquinone, 2-amyl anthraquinone, and 2-aminoanthraquinone; a thioxanthone compound such as 2,4-dimethyl thioxanthone, 2,4-diethyl thioxanthone, 2-chlorothioxanthone, and 2,4-diisopropyl thioxanthone; a ketal compound such as acetophenone dimethyl ketal and benzyl dimethyl ketal; a benzophenone compound such as benzophenone, methyl benzophenone, 4,4′-dichlorobenzophenone, 4,4′-bis(diethyl amino)benzophenone, Michler's ketone, and 4-benzoyl-4′-methyl diphenyl sulfide; an imidazole compound such as a 2-(o-chlorophenyl)-4,5-diphenyl imidazole dimer, a 2-(o-chlorophenyl)-4,5-di(m-methoxyphenyl)imidazole dimer, a 2-(o-fluorophenyl)-4,5-diphenyl imidazole dimer, a 2-(o-methoxyphenyl)-4,5-diphenyl imidazole dimer, a 2-(p-methoxyphenyl)-4,5-diphenyl imidazole dimer, a 2,4-di(p-methoxyphenyl)-5-phenyl imidazole dimer, and a 2-(2,4-dimethoxyphenyl)-4,5-diphenyl imidazole dimer; an acridine compound such as 9-phenyl acridine and 1,7-bis(9,9′-acridinyl) heptane; an acyl phosphine oxide compound such as 2,4,6-trimethyl benzoyl diphenyl phosphine oxide; an oxime ester compound such as 1,2-octane dione-1-[4-(phenyl thio)phenyl]-2-(O-benzoyl oxime), 1-[9-ethyl-6-(2-methyl benzoyl)-9H-carbazol-3-yl]ethanone 1-(0-acetyl oxime), and 1-phenyl-1,2-propane dione-2-[O-(ethoxycarbonyl) oxime]; and a tertiary amine compound such as N,N-dimethyl aminobenzoic acid ethyl ester, N,N-dimethyl aminobenzoic acid isoamyl ester, pentyl-4-dimethyl aminobenzoate, triethyl amine, and triethanol amine.

Only one type of the component (B) may be used alone, or two or more types thereof may be used together. In a case where two or more types of the components (B) are used together, it is preferable to use the acetophenone compound and the thioxanthone compound together, and it is more preferable to use the 2-methyl-1-[4-(methyl thio)phenyl]-2-morpholino-1-propanone and the 2,4-diethyl thioxanthone together.

The content of the component (B) in the photosensitive resin composition is not particularly limited, and may be 0.1 to 15% by mass, 0.15 to 5% by mass, 0.15 to 1.5% by mass, or 0.18 to 1.2% by mass, on the basis of the total solid content of the photosensitive resin composition. In a case where the content of the component (B) is 0.1% by mass or more, there is a tendency that elution in an exposed area during developing when forming a resist pattern is easily suppressed, and in a case where the content of the component (B) is 15% by mass or less, there is a tendency that the heat resistance of the cured product is easily improved.

### (Component (C): Photopolymerizable Compound)

The photosensitive resin composition according to this embodiment, from the viewpoint of increasing chemical resistance after exposure and increasing a difference in developer resistance between an exposed portion and an unexposed portion, contains the photopolymerizable compound as a component (C). The component (C) is not particularly limited insofar as the component is a photopolymerizable compound that has an ethylenically unsaturated group but does not have an acid group.

Examples of the component (C) include a photopolymerizable compound having one ethylenically unsaturated group, a photopolymerizable compound having two ethylenically unsaturated groups, and a photopolymerizable compound having three or more ethylenically unsaturated groups.

Examples of the photopolymerizable compound having one ethylenically unsaturated group include a (meth)acrylic acid and (meth)acrylic acid alkyl ester. Examples of the (meth)acrylic acid alkyl ester include (meth)acrylic acid methyl ester, (meth)acrylic acid ethyl ester, (meth)acrylic acid butyl ester, (meth)acrylic acid 2-ethyl hexyl ester, and (meth)acrylic acid hydroxyl ethyl ester.

Examples of the photopolymerizable compound having two ethylenically unsaturated groups include polyethylene glycol di(meth)acrylate, trimethylol propane di(meth)acrylate, polypropylene glycol di(meth)acrylate, 2,2-bis(4-(meth)acryloxypolyethoxypolypropoxyphenyl) propane, and bisphenol A diglycidyl ether di(meth)acrylate.

Examples of the photopolymerizable compound having three or more ethylenically unsaturated groups include a (meth)acrylate compound having a skeleton derived from trimethylol propane, such as trimethylol propane tri(meth)acrylate; a (meth)acrylate compound having a skeleton derived from tetramethylol methane, such as tetramethylol methane tri(meth)acrylate and tetramethylol methane tetra(meth)acrylate; a (meth)acrylate compound having a skeleton derived from pentaerythritol, such as pentaerythritol tri(meth)acrylate and pentaerythritol tetra(meth)acrylate; a (meth)acrylate compound having a skeleton derived from dipentaerythritol, such as dipentaerythritol penta(meth)acrylate and dipentaerythritol hexa(meth)acrylate; a (meth)acrylate compound having a skeleton derived from ditrimethylol propane, such as ditrimethylol propane tetra(meth)acrylate; and a (meth)acrylate compound having a skeleton derived from diglycerine.

Among them, from the viewpoint of increasing the chemical resistance after exposure and increasing the difference in the developer resistance between the exposed portion and the unexposed portion, the (meth)acrylate compound having a skeleton derived from dipentaerythritol is preferable, and the dipentaerythritol penta(meth)acrylate and the dipentaerythritol hexa(meth)acrylate are more preferable.

In a case where the photosensitive resin composition of this embodiment contains the component (C), the content thereof may be 1 to 20% by mass, 2 to 15% by mass, or 4 to 12% by mass, on the basis of the total solid content of the photosensitive resin composition.

### (Component (D): Thermosetting Resin)

The photosensitive resin composition according to this embodiment contains the thermosetting resin as a component (D). By containing the component (D), it is possible to form the cured product excellent in the bonding adhesiveness. Only one type of the component (D) may be used alone, or two or more types thereof may be used in combination.

Examples of the component (D) include an epoxy resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Among them, from the viewpoint of being more excellent in the bonding adhesiveness of the cured product, the epoxy resin is preferable.

Examples of the epoxy resin include a bisphenol-type epoxy resin such as a bisphenol A-type epoxy resin, a bisphenol F-type epoxy resin, and a bisphenol S-type epoxy resin; a novolac-type epoxy resin such as a bisphenol-based novolac-type epoxy resin, a phenol novolac-type epoxy resin, a cresol novolac-type epoxy resin, and a biphenyl novolac-type epoxy resin; a phenol aralkyl-type epoxy resin; a stilbene-type epoxy resin; a naphthalene skeleton-containing epoxy resin such as a naphthalene-type epoxy resin, a naphthol novolac-type epoxy resin, a naphthol-type epoxy resin, a naphthol aralkyl-type epoxy resin, and a naphthylene ether-type epoxy resin; a biphenyl-type epoxy resin; a biphenyl aralkyl-type epoxy resin; a xylene-type epoxy resin; a dihydroanthracene-type epoxy resin; an alicyclic epoxy resin such as a dicyclopentadiene-type epoxy resin; a heterocyclic epoxy resin; a spiro ring-containing epoxy resin; a cyclohexane dimethanol-type epoxy resin; a trimethylol-type epoxy resin; an aliphatic chain epoxy resin; and a rubber-modified epoxy resin.

Among them, from the viewpoint of being more excellent in the heat resistance, the bonding adhesiveness, and the electrical insulating reliability of the cured product and being capable of further reducing the residue in the bottom portion of the via when formed, it is preferable to use at least one type selected from the bisphenol-type epoxy resin, the phenol novolac-type epoxy resin, the naphthol-type epoxy resin, the naphthalene-type epoxy resin, the biphenyl-type epoxy resin, the naphthylene ether-type epoxy resin, and the cresol novolac-type epoxy resin, as the epoxy resin.

The content of the component (D) in the photosensitive resin composition may be 2 to 30% by mass, 5 to 25% by mass, or 8 to 20% by mass, on the basis of the total solid content of the photosensitive resin composition. In a case where the content of the component (D) is in the range described above, it is possible to further improve the heat resistance of the cured film to be formed while maintaining an excellent developing property.

### (Component (E): Inorganic Filler)

The photosensitive resin composition according to this embodiment may further contain an inorganic filler as a component (E). By containing the component (E), it is possible to improve the bonding adhesiveness, the reliability, and the like of the cured product. Only one type of the component (E) may be used alone, or two or more types thereof may be used in combination.

Examples of the inorganic filler include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, yttria-containing zirconia, barium silicate, boron nitride, calcium carbonate, barium sulfate, calcium sulfate, zinc oxide, magnesium titanate, hydrotalcite, mica, calcined kaolin, and carbon.

The component (E), from the viewpoint of improving the heat resistance of the cured product, may include silica, and from the viewpoint of improving the heat resistance and the bonding adhesive strength of the cured product, may include barium sulfate. From the viewpoint of improving the dispersibility of the inorganic filler, an inorganic filler of which the surface is treated in advance with an alumina or an organic silane compound may be used.

The average particle size of the inorganic filler, from the viewpoint of the resolution, is preferably 0.01 to 5.0 μm, more preferably 0.1 to 3.0 μm, even more preferably 0.3 to 2.0 μm, and particularly preferably 0.5 to 1.5 μm.

In a case where the photosensitive resin composition of this embodiment contains the component (E), the content thereof may be 5 to 80% by mass, 10 to 60% by mass, 15 to 50% by mass, 20 to 45% by mass, 25 to 40% by mass, or 30 to 40% by mass, on the basis of the total solid content of the photosensitive resin composition. In a case where the content of the component (E) is in the range described above, it is possible to improve the resolution, the mechanical strength and the heat resistance of the cured product, and the like.

### (Component (F): Pigment)

The photosensitive resin composition of this embodiment, from the viewpoint of improving the distinguishability or the appearance of a production facility, may further contain a pigment as a component (F). As the component (F), a colorant that produces a desired color when hiding wiring can be used. Examples of the component (F) include phthalocyanine blue, phthalocyanine green, iodine green, diazo yellow, crystal violet, titanium oxide, carbon black, and naphthalene black.

The content of the component (F), from the viewpoint of hiding the wiring, may be 0.1 to 10% by mass, 0.5 to 8% by mass, or 1 to 5% by mass, on the basis of the total solid content in the photosensitive resin composition.

### (Component (G): Elastomer)

The photosensitive resin composition according to this embodiment may further contain an elastomer as a component (G). By containing the component (G), it is possible to suppress a decrease in flexibility and a bonding adhesive strength caused by strain (an internal stress) in the resin due to the curing shrinkage of the component (A). In addition, by containing the component (G), there is a tendency that the resolution of the photosensitive resin composition, and the bonding adhesiveness and the electrical insulating reliability of the cured product are easily improved. Only one type of the component (G) may be used alone, or two or more types thereof may be used together.

Examples of the component (G) include a styrene-based elastomer, an olefin-based elastomer, a urethane-based elastomer, a polyester-based elastomer, a polyamide-based elastomer, an acrylic elastomer, and a silicone-based elastomer. Such elastomers are composed of a hard segment component contributing to the heat resistance and the strength, and a soft segment component contributing to flexibility and toughness.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As the component configuring the styrene-based elastomer, a styrene derivative such as α-methyl styrene, 3-methyl styrene, 4-propyl styrene, and 4-cyclohexyl styrene can be used, in addition to styrene.

The number average molecular weight of the styrene-based elastomer may be 1000 to 50000, or 3000 to 20000. In this specification, the number average molecular weight is a value obtained in terms of standard polystyrene by gel permeation chromatography (GPC) using tetrahydrofuran as a solvent.

Examples of the olefin-based elastomer include a polymer or a copolymer of α-olefin having 2 to 20 carbon atoms, such as ethylene, propylene, 1-butene, 1-hexene, and 4-methyl-pentene; a copolymer of α-olefin having 2 to 20 carbon atoms and non-conjugated diene having 2 to 20 carbon atoms, such as dicyclopentadiene, 1,4-hexadiene, cyclooctadiene, methylene norbornene, ethylidene norbornene, butadiene, and isoprene; and a carboxylic acid-modified butadiene-acrylonitrile copolymer. Specifically, examples of the olefin-based elastomer include polyethylene, polybutadiene, hydroxyl group-containing polybutadiene, hydroxyl group-containing polyisopropylene, an ethylene-propylene copolymer (EPR), and an ethylene-propylene-diene copolymer (EPDM).

The number average molecular weight of the olefin-based elastomer may be 1000 to 8000, or 1500 to 6500.

As the polyester-based elastomer, a compound in which a dicarboxylic acid or a derivative thereof, and a diol compound or a derivative thereof are polycondensed can be used.

Examples of the dicarboxylic acid include an aromatic dicarboxylic acid such as a terephthalic acid, an isophthalic acid, and a naphthalene dicarboxylic acid; an aliphatic dicarboxylic acid having 2 to 20 carbon atoms, such as an adipic acid, a sebacic acid, and a dodecane dicarboxylic acid; and an alicyclic dicarboxylic acid such as a cyclohexane dicarboxylic acid.

Examples of the diol compound include aliphatic diol such as ethylene glycol, 1,3-propane diol, 1,4-butane diol, 1,6-hexane diol, and 1,10-decane diol; alicyclic diol such as 1,4-cyclohexane diol; and aromatic diol such as bisphenol A, bis(4-hydroxyphenyl) methane, bis(4-hydroxy-3-methyl phenyl) propane, and resorcine.

As the polyester-based elastomer, a multiblock copolymer in which aromatic polyester (for example, polybutylene terephthalate) is used for a hard segment component, and aliphatic polyester (for example, polytetramethylene glycol) is used for a soft segment component can be used. There are various grades of polyester-based elastomers, in accordance with a difference in the type, the ratio, and the molecular weight of the hard segment and the soft segment. Examples of a commercially available product of the multiblock copolymer include “Hytrel (Registered Trademark)” (manufactured by DU PONT-TORAY CO., LTD.), “PELPRENE (Registered Trademark)” (manufactured by TOYOBO CO., LTD.), and “Espel (Registered Trademark)” and “Teslac (Registered Trademark)” (manufactured by Resonac Corporation).

The number average molecular weight of the polyester-based elastomer may be 900 to 30000, 1000 to 25000, or 5000 to 20000.

As the urethane-based elastomer, a compound composed of a hard segment consisting of low-molecular-weight (short-chain) diol and diisocyanate, and a soft segment consisting of high-molecular-weight (long-chain) diol and diisocyanate can be used.

Examples of the short-chain diol include ethylene glycol, propylene glycol, 1,4-butane diol, and bisphenol A. It is preferable that the number average molecular weight of the short-chain diol is 48 to 500.

Examples of the long-chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate). It is preferable that the number average molecular weight of the long-chain diol is 500 to 10000.

The number average molecular weight of the urethane-based elastomer may be 1000 to 25000, 1500 to 20000, or 2000 to 15000.

The polyamide-based elastomer is broadly divided into two types of a polyether block amide-type elastomer and a polyether ester block amide-type elastomer, in which polyamide is used for a hard segment, and polyether or polyester is used for a soft segment. Examples of the polyamide include polyamide-6, polyamide-11, and polyamide-12. Examples of the polyether include polyoxyethylene glycol, polyoxypropylene glycol, and polytetramethylene glycol.

The number average molecular weight of the polyamide-based elastomer may be 1000 to 50000, or 2000 to 30000.

As the acrylic elastomer, a compound containing a constitutional unit based on (meth)acrylic acid ester as a main component can be used. Examples of the (meth)acrylic acid ester include methyl (meth)acrylate, ethyl (meth)acrylate, butyl (meth)acrylate, methoxyethyl (meth)acrylate, and ethoxyethyl (meth)acrylate. The acrylic elastomer may be a compound in which (meth)acrylic acid ester and acrylonitrile are copolymerized, or may be a compound in which a monomer having a functional group to be a cross-linking point is further copolymerized. Examples of the monomer having a functional group include glycidyl methacrylate and allyl glycidyl ether.

Examples of the acrylic elastomer include an acrylonitrile-butyl acrylate copolymer, an acrylonitrile-butyl acrylate-ethyl acrylate copolymer, a methyl methacrylate-butyl acrylate-methacrylic acid copolymer, and an acrylonitrile-butyl acrylate-glycidyl methacrylate copolymer.

The number average molecular weight of the acrylic elastomer may be 1000 to 50000, or 2000 to 30000.

The silicone-based elastomer is a compound containing organopolysiloxane as a main component. Examples of the organopolysiloxane include polydimethyl siloxane, polymethyl phenyl siloxane, and polydiphenyl siloxane. The silicone-based elastomer may be a compound in which a part of organopolysiloxane is modified with a vinyl group, an alkoxy group, or the like.

The number average molecular weight of the silicone-based elastomer may be 1000 to 50000, or 2000 to 30000.

From the viewpoint of the compatibility and the solubility of the photosensitive resin composition with respect to the other components, and the bonding adhesiveness of the cured product, the component (G) includes preferably at least one type selected from the group consisting of the olefin-based elastomer, the polyester-based elastomer, and the urethane-based elastomer, and more preferably the polyester-based elastomer. From the same viewpoint, it is preferable that the component (G) is an elastomer in the form of a liquid at a room temperature.

In a case where the photosensitive resin composition of this embodiment contains the component (G), the content thereof may be 0.5 to 20% by mass, 0.5 to 15% by mass, 0.5 to 10% by mass, 1.0 to 6% by mass, or 1.0 to 4.0% by mass, on the basis of the total solid content of the photosensitive resin composition. In a case where the content of the component (G) is in the range described above, there is a tendency of being more excellent in the resolution, and the bonding adhesiveness and the electrical insulating reliability of the cured product.

### (Other Components)

The photosensitive resin composition according to this embodiment, as necessary, may further contain various additives. Examples of the additive include a thermal polymerization initiator; a polymerization inhibitor such as hydroquinone, methyl hydroquinone, hydroquinone monomethyl ether, catechol, and pyrogallol; a thickener such as bentone and montmorillonite; silicone-based, fluorine-based, and vinyl resin-based antifoaming agents; a silane coupling agent; a flame retarder such as a brominated epoxy compound, an acid-modified brominated epoxy compound, an antimony compound, a phosphate compound, aromatic condensed phosphoric acid ester, and halogen-containing condensed phosphoric acid ester; and a thermoplastic resin such as a polyester polyurethane resin.

### (Solvent)

In the photosensitive resin composition according to this embodiment, as necessary, a solvent can be used. By the photosensitive resin composition according to this embodiment containing the solvent for dissolving and dispersing each component, the photosensitive resin composition according to this embodiment can be easily applied onto a substrate to form a coated film with an even thickness, which enables the formation of a higher-definition pattern.

Examples of the solvent include an organic solvent. Examples of the organic solvent include ketone such as methyl ethyl ketone and cyclohexanone; aromatic hydrocarbon such as toluene, xylene, and tetramethyl benzene; glycol ether such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; ester such as ethyl acetate, butyl acetate, propylene glycol monoethyl ether acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Among them, the ketone and the ester are preferable, and the ester is more preferable. Only one type of the solvent may be used alone, or two or more types thereof may be used together.

The blending amount of the solvent may be suitably selected such that the concentration of the total solid content in the photosensitive resin composition is 40 to 90% by mass, 45 to 80% by mass, or 45 to 70% by mass.

The photosensitive resin composition of this embodiment can be prepared by homogeneously mixing each component described above with a roll mill, a bead mill, or the like. The photosensitive resin composition of this embodiment may be used in a liquid state, or may be used in a film state as with a photosensitive element described below.

### [Photosensitive Element]

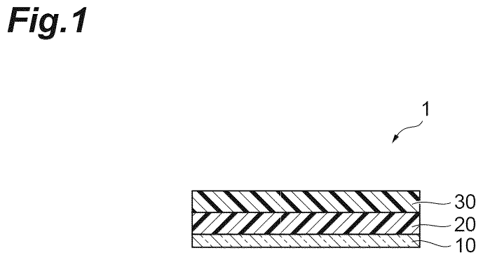

A photosensitive element according to this embodiment includes a support film, and a photosensitive layer containing the photosensitive resin composition described above. FIG. 1 is a cross-sectional view schematically illustrating the photosensitive element according to this embodiment. As illustrated in FIG. 1, a photosensitive element 1 includes a support film 10, and a photosensitive layer 20 formed on the support film 10. The photosensitive element 1 may further include a protective film 30 on the photosensitive layer 20.

The photosensitive element 1 can be produced by applying the photosensitive resin composition according to this embodiment onto the support film 10 with a known coating machine such as a comma coater, a bar coater, a kiss coater, a roll coater, a gravure coater, and a die coater, and then, drying the coated film to form the photosensitive layer 20. The thickness of the photosensitive layer is not particularly limited, and from the viewpoint of making a printed circuit board thin, may be 1 to 100 μm, 1 to 50 μm, or 5 to 40 μm.

The coated film can be dried by using a hot-air dryer, a dryer using a far infrared ray or a near infrared ray, or the like. A drying temperature may be 60 to 150° C., 70 to 120° C., or 80 to 100° C. A drying time may be 1 to 60 minutes, 2 to 30 minutes, or 5 to 20 minutes. The content of the residual solvent in the coated film after drying, from the viewpoint of avoiding the diffusion of the solvent in a step of producing a printed circuit board, may be 3% by mass or less, 2% by mass or less, or 1% by mass or less.

Examples of the support film include a polyester film such as a polyethylene terephthalate film and a polybutylene terephthalate film; and a polyolefin film such as a polypropylene film and a polyethylene film. The thickness of the support film, for example, may be 5 to 100 μm, 5 to 60 μm, or 15 to 45 μm.

As the protective film 30, for example, a polymer film such as polyethylene and polypropylene may be used. As the protective film 30, the same film as the support film 10 may be used, or a different film may be used.

The photosensitive resin composition according to this embodiment is suitable as a permanent resist such as an interlayer dielectric layer of a printed circuit board. In addition, the photosensitive resin composition according to this embodiment is also useful to form a cavity for having a chip, a passive element, or the like built-in. The photosensitive resin composition according to this embodiment is also useful to form a surface protective layer of a printed circuit board.

### [Printed Circuit Board]

A printed circuit board according to this embodiment includes an interlayer dielectric layer including a cured product of the photosensitive resin composition according to this embodiment.

A method for producing a printed circuit board according to this embodiment includes a step of forming a photosensitive layer on a substrate by using the photosensitive resin composition or the photosensitive element according to this embodiment, a step of exposing and developing the photosensitive layer to form a resist pattern, and a step of curing the resist pattern to form an interlayer dielectric layer.

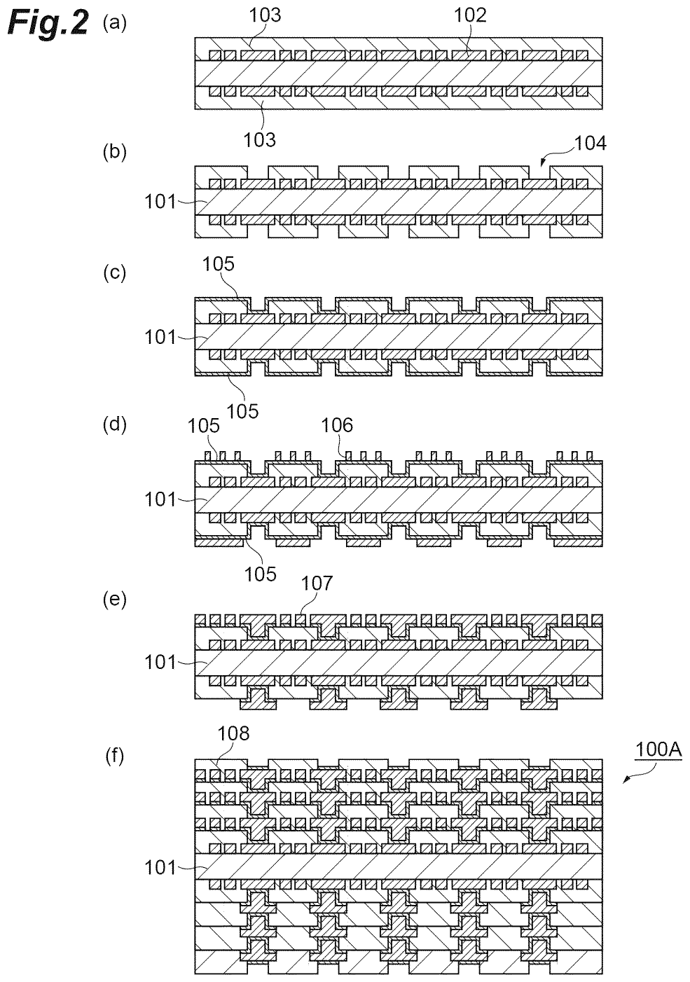

FIG. 2 is a schematic cross-sectional view illustrating an example of a method for producing a multilayer printed circuit board including the cured product of the photosensitive resin composition according to this embodiment as the interlayer dielectric layer. A multilayer printed circuit board 100A illustrated in (f) in FIG. 2 has a wiring pattern on the surface and inside. The multilayer printed circuit board 100A can be obtained by stacking a copper clad laminate, an interlayer dielectric layer, a metal foil, and the like, and suitably forming a wiring pattern by an etching method or a semi-additive method. Hereinafter, a method for producing the multilayer printed circuit board 100A will be simply described on the basis of FIG. 2.

First, an interlayer dielectric layer 103 is formed on both surfaces of a base material (for example, a copper clad laminate) 101 having a wiring pattern 102 on the surface (refer to (a) in FIG. 2). The interlayer dielectric layer 103 may be formed by printing the photosensitive resin composition according to this embodiment using a screen printer or a roll coater, and can also be formed by preparing in advance the photosensitive element according to this embodiment, and sticking the photosensitive layer of the photosensitive element to the surface of the base material 101 using a laminator.

Next, a via (an opening portion) 104 is formed by using YAG laser or carbonate gas laser in a portion required to be electrically connected to the outside (refer to (b) in FIG. 2). A smear (a residue) around the via 104 can be removed by a desmear treatment.

Next, a seed layer 105 is formed by an electroless plating method (refer to (c) in FIG. 2). The photosensitive layer containing the photosensitive resin composition is formed on the seed layer 105, and a predetermined portion is exposed and developed to form a resin pattern 106 (refer to (d) in FIG. 2).

Next, a wiring pattern 107 is formed by an electrolytic plating method in a portion of the seed layer 105 in which the resin pattern 106 is not formed. Then, the resin pattern 106 is removed with a peeling liquid, and then, a portion of the seed layer 105 in which the wiring pattern 107 is not formed is removed by etching (refer to (e) in FIG. 2).

By repeating the operations described above to form a solder resist 108 including the cured product of the photosensitive resin composition according to this embodiment on the outermost surface, it is possible to produce the multilayer printed circuit board 100A (refer to (f) in FIG. 2). In the multilayer printed circuit board 100A obtained as described above, for example, a semiconductor element is mounted in the corresponding portion, and electrical connection can be ensured.

By using the photosensitive resin composition according to this embodiment, it is possible to produce the semiconductor element including the interlayer dielectric layer formed from the cured product of the photosensitive resin composition described above, and an electronic device including the semiconductor element. The semiconductor element, for example, may be a memory, a package, or the like, which has a multilayer wiring structure, a redistribution structure, and the like. Examples of the electronic device include a mobile phone, a smart phone, a tablet terminal, a personal computer, and a hard disk suspension. By including the pattern cured product formed by the photosensitive resin composition according to this embodiment, it is possible to provide the semiconductor element and the electronic device excellent in reliability.

### EXAMPLES

Hereinafter, the present disclosure will be described in more detail by Examples, but the present disclosure is not limited to such Examples.

### Synthesis Example 1

250 parts by mass of a dicyclopentadiene-type epoxy resin (manufactured by Nippon Kayaku Co., Ltd., Product Name “XD-1000”), 70 parts by mass of an acrylic acid, 0.5 parts by mass of methyl hydroquinone, and 120 parts by mass of carbitol acetate were mixed while stirring at 90° C. The mixed liquid was cooled to 60° C., and 2 parts by mass of triphenyl phosphine was added thereto to cause a reaction until the acid value of the solution at 100° C. was 1 mgKOH/g. 98 parts by mass of a tetrahydrophthalic anhydride and 850 parts by mass of carbitol acetate were added to the reaction liquid, and heated to 80° C. to cause a reaction for 6 hours. After that, the reaction liquid was cooled to a room temperature to obtain a solution (a solid content concentration of 65% by mass) of an acid-modified epoxy acrylate resin (A-1) as a first resin of a component (A). Mw of the obtained acid-modified epoxy acrylate resin (A-1) was 1800.

### Synthesis Example 2

350 parts by mass of a bisphenol F novolac-type epoxy resin (manufactured by DIC Corporation, Product Name “EXA-7376”), 70 parts by mass of an acrylic acid, 0.5 parts by mass of methyl hydroquinone, and 120 parts by mass of carbitol acetate were mixed while stirring at 90° C. The mixed liquid was cooled to 60° C., and 2 parts by mass of triphenyl phosphine was added thereto to cause a reaction until the acid value of the solution at 100° C. was 1 mgKOH/g or less. 98 parts by mass of a tetrahydrophthalic anhydride and 850 parts by mass of carbitol acetate were added to the reaction liquid to cause a reaction at 80° C. for 6 hours. After that, the reaction liquid was cooled to a room temperature to obtain a solution (Solid Content Concentration: 73% by mass) of acid-modified epoxy acrylate (A-2) as the component (A). Mw of the obtained acid-modified epoxy acrylate resin (A-2) was 4500.

As components (B) to (F), the following materials were prepared.
B-1: 2-methyl-[4-(methyl thio)phenyl]-2-morpholino-1-propane (IGM Resins B.V., Product Name “Omnirad 907”)
B-2: 2,4-diethyl thioxanthone (manufactured by Nagase & Co., Ltd., Product Name “SB-PI799”)
C-1: dipentaerythritol hexaacrylate (manufactured by Nippon Kayaku Co., Ltd., Product Name “DPHA”)
C-2: dicyclopentanyl acrylate (manufactured by Resonac Corporation, Product Name “FA-513AS”)
D-1: a bisphenol novolac-type epoxy resin (manufactured by Nippon Kayaku Co., Ltd., Product Name “RE-306”)
D-2: a tetramethyl biphenol-type epoxy resin (manufactured by Mitsubishi Chemical Corporation, Product Name “YX4000”)
E-1: silica (an average particle size of 0.5 μm) (manufactured by ADMATECHS COMPANY LIMITED, ADMAFINE (Registered Trademark))
F-1: a phthalocyanine-based pigment (manufactured by SANYO COLOR WORKS, Ltd.)

### [Photosensitive Resin Composition]

Each component was blended in a blending amount (parts by mass, in terms of a solid content) shown in Table 1, and kneaded with a three-roll mill. After that, carbitol acetate was added such that the solid content concentration was 60% by mass, and a photosensitive resin composition was prepared.

### [Photosensitive Element]

As a support film, a polyethylene terephthalate film (manufactured by TEIJIN LIMITED, Product Name “G2-16”) with a thickness of 16 μm was prepared. The photosensitive resin composition was applied onto the support film such that a thickness after drying was 18 μm, and dried at 75° C. for 30 minutes by using a hot-air convection dryer to form a photosensitive layer. Next, a polyethylene film (manufactured by TAMAPOLY CO., LTD., Product Name “NF-15”) was stuck onto the surface of the photosensitive layer on a side opposite to the surface in contact with the support film as a protective film to obtain a photosensitive element.

### (Evaluation of Residue in Bottom Portion)

A copper clad laminate (manufactured by Resonac Corporation, Product Name “MCL-E-67”) with a thickness of 0.6 mm was prepared. While peeling and removing the protective film from the photosensitive element, the photosensitive layer was laminated on the copper clad laminate by using a press-type vacuum laminator (manufactured by MEIKI CO., LTD., Product Name “MVLP-500”), in a condition of Crimping Pressure: 0.4 MPa, Press Hot Plate Temperature: 80° C., Vacuumizing Time: 25 seconds, Laminating Press Time: 25 seconds, and Atmospheric Pressure: 4 kPa or less, to obtain a stacked body. Next, the photosensitive layer was exposed through a negative mask having a via pattern with an opening diameter of 30 μm by using an i-line exposure machine (manufactured by Ushio Inc., Product Name “UX-2240SM-XJ-01”) while changing an exposure energy amount by 50 mJ/cm² in a range of 100 to 1000 mJ/cm². After that, spray development was performed by using 1% by mass of a sodium carbonate aqueous solution at 30° C. and a pressure of 1.765×10⁵ Pa for a time period corresponding to 2.5 times the shortest developing time (the shortest time required for an unexposed portion of the photosensitive layer to be removed) to dissolve and develop the unexposed portion. Next, exposure was performed in an exposure amount of 2000 mJ/cm² by using an ultraviolet ray exposure machine to produce a test piece including a cured film in which the via pattern with an opening diameter of 30 μm was provided on the copper clad laminate. For the test piece, the presence or absence of a residue in the bottom portion of the via pattern portion was checked with a scanning electronic microscope. The evaluation was performed on the basis of the following criteria. Results are shown in Table 1.

### <Evaluation Criteria>

A: the residue was not observed in the bottom portion.
B: the residue was observed in a part of the bottom portion.
C: the residue was observed on the entire surface of the bottom portion.

TABLE 1

| | | | Example | | | Comparative Example | | |
|---|---|---|---|---|---|---|---|---|
| Component | | Unit | 1 | 2 | 3 | 1 | 2 | 3 |
| Component (A) | A-1 | Parts by | 10.85 | 12.36 | 13.99 | 23.20 | 16.24 | 11.60 |
| | | mass | | | | | | |
| | A-2 | Parts by | 4.65 | 5.30 | 6.00 | — | 6.96 | 11.60 |
| | | mass | | | | | | |
| Component (B) | B-1 | Parts by | 0.07 | 0.07 | 0.07 | 0.07 | 0.07 | 0.07 |
| | | mass | | | | | | |
| | B-2 | Parts by | 0.05 | 0.05 | 0.05 | 0.05 | 0.05 | 0.05 |
| | | mass | | | | | | |
| Component (C) | C-1 | Parts by | 4.25 | 4.25 | 4.25 | 4.25 | 4.25 | 4.25 |
| | | mass | | | | | | |
| | C-2 | Parts by | 2.00 | 2.00 | 2.00 | 2.00 | 2.00 | 2.00 |
| | | mass | | | | | | |
| Component (D) | D-1 | Parts by | 2.23 | 2.23 | 2.23 | 2.23 | 2.23 | 2.23 |
| | | mass | | | | | | |
| | D-2 | Parts by | 7.54 | 7.54 | 7.54 | 7.54 | 7.54 | 7.54 |
| | | mass | | | | | | |
| Component (E) | E-1 | Parts by | 26.78 | 26.78 | 26.78 | 26.78 | 26.78 | 26.78 |
| | | mass | | | | | | |
| Component (F) | F-1 | Parts by | 1.18 | 1.18 | 1.18 | 1.18 | 1.18 | 1.18 |
| | | mass | | | | | | |

| Content of component (A) | % by | 26 | 29 | 31 | 34 | 34 | 34 |
|---|---|---|---|---|---|---|---|
| | mass | | | | | | |
| Ratio of first resin in | % by | 70 | 70 | 70 | 100 | 70 | 50 |
| component (A) | mass | | | | | | |

| | | | | | | |
|---|---|---|---|---|---|---|
| Residue in bottom portion | A | A | A | B | B | C |

### REFERENCE SIGNS LIST

1: photosensitive element, 10: support film, 20: photosensitive layer, 30: protective film, 100A: multilayer printed circuit board, 101: base material, 102, 107: wiring pattern, 103: interlayer dielectric layer, 104: via, 105: seed layer, 106: resin pattern, 108: solder resist.

1. A photosensitive resin composition, comprising:
an acid-modified vinyl group-containing resin (A);
a photopolymerization initiator (B);
a photopolymerizable compound (C); and
a thermosetting resin (D),
wherein the acid-modified vinyl group-containing resin (A) contains a first resin with a weight average molecular weight of less than 4000, and a second resin with a weight average molecular weight of 4000 or more,
a content of the first resin is greater than 60% by mass, on the basis of a total amount of the acid-modified vinyl group-containing resin (A), and
a content of the acid-modified vinyl group-containing resin (A) is 33% by mass or less, on the basis of a total solid content of the photosensitive resin composition.

2. The photosensitive resin composition according to claim 1,
wherein the first resin includes acid-modified epoxy (meth)acrylate having an alicyclic skeleton.

3. The photosensitive resin composition according to claim 1,
wherein the second resin includes acid-modified epoxy (meth)acrylate not having an alicyclic skeleton.

4. The photosensitive resin composition according to claim 1,
wherein a content of the second resin is 5% by mass or more, on the basis of the total amount of the acid-modified vinyl group-containing resin (A).

5. The photosensitive resin composition according to claim 1, further comprising
an inorganic filler (E).

6. The photosensitive resin composition according to claim 1, further comprising
a pigment (F).

7. A photosensitive element, comprising:
a support film; and
a photosensitive layer formed on the support film,
wherein the photosensitive layer contains the photosensitive resin composition according to claim 1.

8. A printed circuit board, comprising
an interlayer dielectric layer including a cured product of the photosensitive resin composition according to claim 1.

9. A method for producing a printed circuit board, comprising:
a step of forming a photosensitive layer on a substrate by using the photosensitive resin composition according to claim 1;
a step of exposing and developing the photosensitive layer to form a resist pattern; and
a step of curing the resist pattern to form an interlayer dielectric layer.

10. A method for producing a printed circuit board, comprising:
a step of forming a photosensitive layer on a substrate by using the photosensitive element according to claim 7;
a step of exposing and developing the photosensitive layer to form a resist pattern; and
a step of curing the resist pattern to form an interlayer dielectric layer.
